(19) United States
(12) Patent Application Publication
(10) Pub. No.: US 2009/0001548 A1
(43) Pub. Date: Jan. 1, 2009

(54) Semiconductor package

(75) Inventors: Fumiyuki Osanai, Tokyo (JP); Toshio Sugano, Tokyo (JP); Atsushi Hiraishi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/213,559

(22) Filed: Jun. 20, 2008

(30) Foreign Application Priority Data
Jun. 27, 2007 (JP) P2007-169247

(51) Int. Cl. H01L 23/48

(52) U.S. Cl. 257/691; 257/693; 257/E23.021; 257/E23.079

(57) ABSTRACT

A semiconductor package which includes: a semiconductor chip which includes a signal terminal for inputting and outputting electrical signals and a ground terminal; and a package substrate which includes a semiconductor chip mounting surface on which the semiconductor chip is mounted, and a terminal electrode forming surface on which a signal terminal electrode electrically connected to the signal terminal and a ground terminal electrode electrically connected to the ground terminal are arranged in an array pattern, wherein: on the semiconductor chip mounting surface, there is provided a first signal wiring connected to the signal terminal, a ground wiring connected to the ground terminal, and a ground conductive layer connected to the ground wiring and is provided in a planar pattern in an area excluding the forming area of the first signal wiring; on the terminal electrode forming surface, there is provided a second signal wiring connected to the signal terminal electrode, and a ground fine wiring connected to the ground terminal electrode; and the first signal wiring and the second signal wiring are connected via a conductor filled in a signal through hole penetrating the package substrate, and the ground conductive layer and the ground fine wiring are connected via a conductor filled in a ground through hole penetrating the package substrate.

### BACKGROUND OF THE INVENTION

1. Field of the Invention

The present invention relates to a semiconductor package, and more particularly, to a ball grid array (BGA) semiconductor package.

Priority is claimed on Japanese Patent Application No. 2007-169247, filed Jun. 27, 2007, the content of which is incorporated herein by reference.

2. Description of Related Art

In a semiconductor package fabrication, a semiconductor chip is mounted on a package substrate and then covered with mold resin. An exemplary semiconductor package is a ball grid array (BGA) package, which includes hemispherical external input and output terminals arranged in an array pattern on the bottom surface of a package substrate. The BGA package has advantages such that arranging many external input and output terminals therein and manufacturing the semiconductor package as compact as a semiconductor chip. The BGA package is suitably used in portable electronic apparatuses, such as cellular phones that require high density assembly of semiconductor parts.

Some BGA packages have a multi-layered structure in which multiple package substrates are laminated. However, BGA packages with a single package substrate, in which a semiconductor chip is mounted on a first surface of the package substrate and external input and output terminals are provided on a second surface of the package substrate, are preferred due to simple fabrication process and low cost. An exemplary package substrate used in the BGA package is shown in FIGS. 5A and 5B.

As shown in FIGS. 5A and 5B, a package substrate 101 includes a semiconductor chip mounting surface 102 on which a semiconductor chip is mounted. The package substrate 101 also includes a terminal electrode forming surface 105 on which a plurality of signal terminal electrodes 103 as external input and output terminals, and ground terminal electrodes 104 are arranged in an array pattern.

The semiconductor chip mounting surface 102 includes a semiconductor chip mounting area 106, a plurality of signal wirings 107 and ground wirings 108.

The signal wirings 107 are provided in linear patterns such that first ends thereof are arranged along a substantial longitudinal center of the semiconductor chip mounting area 106 to correspond to the signal terminals of the semiconductor chip, and second ends thereof are positioned in the vicinity of the areas corresponding to the signal terminal electrodes 103 provided on the terminal electrode forming surface 105 (i.e., the opposite side of the areas where the signal terminal electrodes 103 are provided).

The ground wirings 108 are provided in linear patterns such that first ends thereof are arranged along the substantial longitudinal center of the semiconductor chip mounting area 106 alongside the first ends of the signal wirings 107 to correspond to the ground terminals of the semiconductor chip, and second ends thereof are positioned in the vicinity of one outer edge of the semiconductor chip mounting area 106.

On the terminal electrode forming surface 105, there are provided a plurality of signal fine wirings 109 corresponding to the plurality of the signal terminal electrodes 103, and a ground conductive layer 110.

The plurality of the signal fine wirings 109 are provided in short linear patterns with first ends connected to the signal terminal electrodes 103 and second ends connected to later-described conductors 111a provided in through holes 111.

The ground conductive layer 110 is provided at a predetermined area (i.e., a ground area) of the terminal electrode forming surface 105 in a solid (planar) pattern excluding the signal terminal electrodes 103, the signal fine wirings 109, the signal through holes 111, the vicinities of them, and the areas corresponding to the semiconductor chip mounting areas 106 (i.e., the opposite side of the semiconductor chip mounting areas 106). The ground conductive layer 110 is provided so as to contact with the ground terminal electrodes 104. With this configuration, the ground conductive layer 110 is not in conduction with the signal terminal electrodes 103, the signal fine wirings 109 and the conductor 111a in the through holes 111, but in conduction with the ground terminal electrodes 104. In the following description, areas between the ground conductive layer 110 and the signal terminal electrodes 103, the signal fine wirings 109, and the signal through holes 111 (i.e., the areas without the ground conductive layer) are called “clearance”. FIG. 5B shows a ground area of the terminal electrode forming surface 105. Although not illustrated, the signal terminal electrodes 103, the signal fine wirings 109, the signal through holes 111 and the like are similarly provided in the areas excluding the ground area of the terminal electrode forming surface 105.

The signal through holes 111 are provided in the package substrate 101 at positions corresponding to the second ends of the signal wirings 107 and the signal fine wirings 109. The ground through holes 112 are provided in the package substrate 101 at positions corresponding to the second ends of the ground wirings 108.

The signal wirings 107 and the signal fine wirings 109 are electrically connected via the conductors 111a provided in the through holes 111. Similarly, the ground wirings 108 and the ground conductive layer 110 are electrically connected via the conductors 112a provided in the through holes 112.

In the package substrate 101, the signal wirings 107, the conductors 111a in the signal through holes 111, the signal fine wirings 109 and the signal terminal electrodes 103 altogether constitute a signal circuit for transmitting electrical signals fed from the semiconductor chips. Similarly, the ground wirings 108, the conductors 112a in the ground through holes 112, the ground conductive layer 110 and the ground terminal electrodes 104 altogether constitute a ground circuit.

Japanese Unexamined Patent Application, First Publication No. H9-82557 discloses a BGA package used as a by-pass capacitor. In the BGA package, either a first or a second solid pattern is connected to GND in order to connect, to a power supply or GND, the noise on electronic parts mounted on a printed circuit board via a base substrate with electrodes.

Japanese Unexamined Patent Application, First Publication No. 2001-168266 discloses a semiconductor device to which power supply voltage as working voltage having at least three different voltage levels with respect to a reference potential is supplied. In the semiconductor device, a plurality of wiring layers are provided between wiring boards and each wiring layer is formed in a planar solid pattern as a ground plane.

Japanese Unexamined Patent Application, First Publication No. 2002-164469 discloses a semiconductor device including a first wiring tape as a signal wiring layer, and a second wiring tape attached to the first wiring tape as a power supply and a ground wiring layer.

However, in the BGA package with the above-mentioned package substrate 101, the signal current flowing through the signal terminal electrodes 103 and the signal fine wirings 109 may leak into the ground conductive layer 110 over the clearance. Thus, the characteristic impedance of the electrical signals output from the signal terminal electrodes 103 may vary in the area with the ground conductive layer 110 provided in the vicinity thereof (i.e., a ground area) and in the area with no ground conductive layer. Thus, reflected signals may be generated due to mismatched impedance values, impairing the signal quality.

Further, since in the structure with the ground conductive layer 110 provided on the terminal electrode forming surface 105, the signal terminal electrodes 103, the signal fine wirings 109, and the conductors in the signal through holes 111 are not in touch with the ground conductive layer 110, the formation area of the ground conductive layer 110 is restricted greatly. As a result, the area of the ground conductive layer 110 is reduced, and the inductance in the ground circuits increases, thereby generating noise or a malfunction.

Such problems have not been solved by the semiconductor devices disclosed in Japanese Unexamined Patent Application, First Publication No. H9-82557, Japanese Unexamined Patent Application, First Publication No. 2001-168266, and Japanese Unexamined Patent Application, First Publication No. 2002-164469. Thus, there is a need for a semiconductor package with no reflected signals generated from mismatched impedance values or no deterioration in the signal quality.

### SUMMARY OF THE INVENTION

In view of the aforementioned, an object of the present invention is to provide a semiconductor package in which an area of a ground conductive layer can be made sufficiently large, leakage of signal current flowing through a signal circuit into a ground conductive layer can be prevented, and thus signal quality can be kept high.

A semiconductor package according to an aspect of the present invention includes: a semiconductor chip which includes a signal terminal for inputting and outputting electrical signals and a ground terminal; and a package substrate which includes a semiconductor chip mounting surface on which the semiconductor chip is mounted, and a terminal electrode forming surface on which a signal terminal electrode electrically connected to the signal terminal and a ground terminal electrode electrically connected to the ground terminal are arranged in an array pattern, wherein: on the semiconductor chip mounting surface, there is provided a first signal wiring connected to the signal terminal, a ground wiring connected to the ground terminal, and a ground conductive layer connected to the ground wiring and is provided in a planar pattern in an area excluding the forming area of the first signal wiring; on the terminal electrode forming surface, there is provided a second signal wiring connected to the signal terminal electrode, and a ground fine wiring connected to the ground terminal electrode; and the first signal wiring and the second signal wiring are connected via a conductor filled in a signal through hole penetrating the package substrate, and the ground conductive layer and the ground fine wiring are connected via a conductor filled in a ground through hole penetrating the package substrate.

With this structure, the area of the ground conductive layer can be made sufficiently large, leakage of the signal current flowing through the signal circuit into the ground conductive layer can be prevented, and thus the signal quality can be kept high.

In the present invention, the first signal wiring and the ground wiring are preferably formed in the semiconductor chip mounting area and in the vicinity of an outer edge of the semiconductor chip mounting area.

With this structure, leakage of the signal current flowing through the signal circuit into the ground conductive layer can be more successfully prevented, and a larger ground conductive layer can be obtained.

In the present invention, the area of the second signal wiring preferably accounts for not less than 70% of the total area of the first signal wiring and the second signal wiring.

With this structure, a larger ground conductive layer can be obtained.

In the present invention, it is preferable that a first power supply signal wiring connected to a power supply signal terminal of the semiconductor chip and a second power supply signal wiring connected to the first power supply signal wiring be provided on the semiconductor chip mounting surface; a power supply signal terminal electrode and a power supply signal fine wiring connected to the power supply signal terminal electrode be provided on the terminal electrode forming surface; and the second power supply signal wiring and the power supply signal fine wiring be connected via a conductor filled in a power supply signal through hole penetrating the package substrate.

With this structure, the wiring density on the terminal electrode forming surface can be reduced and patterning of the conductor layer used as wirings can be simplified in a wiring formation process.

In the present invention, the second power supply signal wiring is preferably provided to enter the forming area of the ground conductive layer.

With this structure, the second power supply signal wiring can be provided in a wider area and thus inductance on the circuit for the power supply signal can be reduced.

In the present invention, the second power supply signal wiring is preferably wider than the first power supply signal wiring.

With this structure, inductance of the circuit for power supply signal can be sufficiently reduced.

A semiconductor package according to another aspect of the present invention includes: a semiconductor chip which includes a signal terminal for inputting and outputting electrical signals and a ground terminal; and a package substrate which includes a semiconductor chip mounting surface on which the semiconductor chip is mounted, and a terminal electrode forming surface on which a signal terminal electrode electrically connected to the signal terminal and a ground terminal electrode electrically connected to the ground terminal are arranged in an array pattern, wherein: a ground conductive layer connected to the ground terminal electrode and formed in a planar pattern is provided on the semiconductor chip mounting surface; a signal wiring connected to the signal terminal electrode is provided on the terminal electrode forming surface; and the signal terminal electrode and the signal wiring of the semiconductor chip are connected via a conductor filled in a signal through hole penetrating the package substrate, and the ground conductive layer and the ground terminal electrode are connected via a conductor filled in a ground through hole penetrating the package substrate.

With this structure, the area of the ground conductive layer can be made sufficiently large, leakage of the signal current flowing through the signal circuit into the ground conductive layer can be prevented, and thus the signal quality can be kept high.

In the present invention, the signal terminal and the ground terminal of the semiconductor chip are preferably bumps.

With this structure, the signal terminal and the ground terminal of the semiconductor chip can be firmly connected to the semiconductor chip mounting surface of the package substrate in a simple process.

As described above, in accordance with the present invention, since the ground conductive layer is provided on the semiconductor chip mounting surface excluding the forming area of the first signal wiring, and the signal circuit excluding the first signal wiring and the conductor in the through hole is provided on the terminal electrode forming surface, a situation can be avoided in which the components of the signal circuit (i.e., the first signal wiring, the conductor in the through hole, the second signal wiring and the signal terminal electrode) and the ground conductive layer approach closely. In this manner, leakage of the signal current flowing through the signal circuit into the ground conductive layer can be prevented. The characteristic impedance of the electrical signals output from the signal terminal electrode can be made substantially equal in the ground area and in the rest of the area. Thus, the signal quality can be kept high.

Since the area for wiring is controlled, the ground conductive layer provided on the semiconductor chip mounting surface can be made comparatively large. In this manner, inductance of the ground circuit decreases and the generation of noise or a malfunction can be avoided.

Further, in accordance with the present invention, since the ground conductive layer is provided on the semiconductor chip mounting surface, and the signal circuit other than the conductor in the through hole is provided on the terminal electrode forming surface, a situation can be avoided in which the components of the signal circuit (i.e., the conductor in the through hole, the signal wiring and the signal terminal electrode) and the ground conductive layer approach closely. In this manner, leakage of the signal current flowing through the signal circuit into the ground conductive layer can be prevented. The characteristic impedance of the electrical signals output from the signal terminal electrode can be made substantially equal in the ground area and in the rest of the area. Thus, the signal quality can be kept high.

Further, in this case, the ground conductive layer can be formed in a large area since it can be provided on substantially the entire area of the semiconductor chip mounting surface excluding the signal through hole and the vicinity thereof. As a result, the inductance in the ground circuits decreases to prevent the generation of noise or a malfunction.

### BRIEF DESCRIPTION OF THE DRAWINGS

FIG. 1 is a longitudinal cross-sectional view of a semiconductor package according to a first embodiment of the present invention.

FIG. 2A is a plan view, and FIG. 2B is a back view of a package substrate used in the semiconductor package according to the first embodiment.

FIG. 3A is a plan view, and FIG. 3B is a back view of a package substrate used in a semiconductor package according to a second embodiment.

FIG. 4A is a plan view, and FIG. 4B is a plan view of a package substrate used in a semiconductor package according to a third embodiment.

FIG. 5A is a plan view, and FIG. 5B is a plan view of a package substrate used in a conventional semiconductor package.

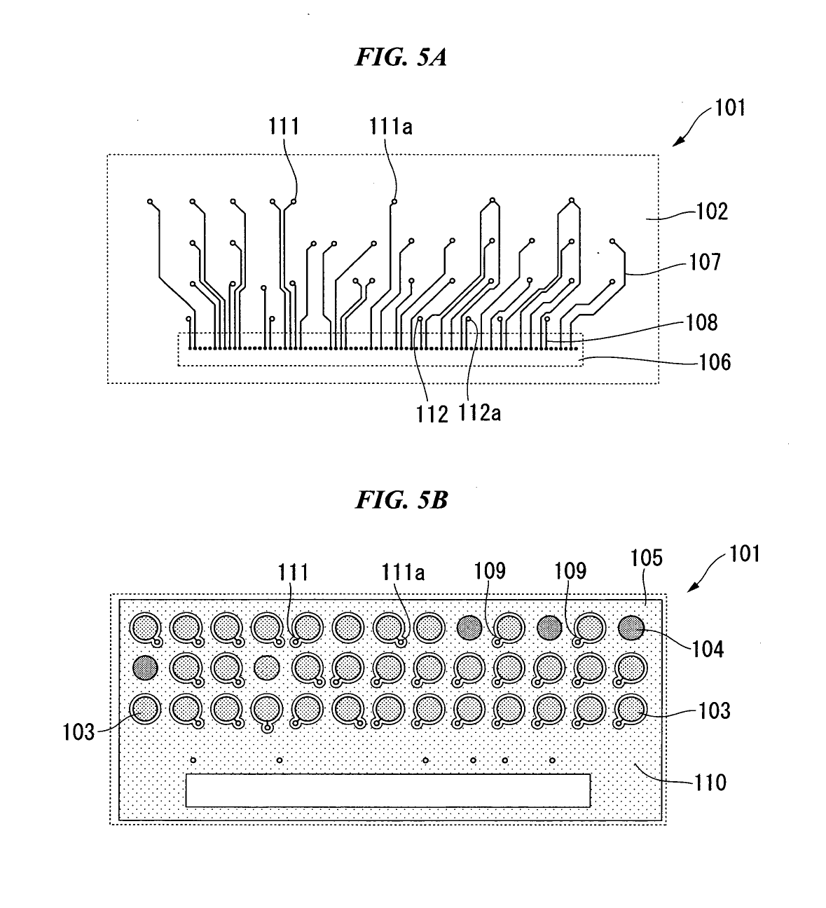

### DETAILED DESCRIPTION OF THE INVENTION

Referring now to the drawings, a semiconductor package of the present invention will be described.

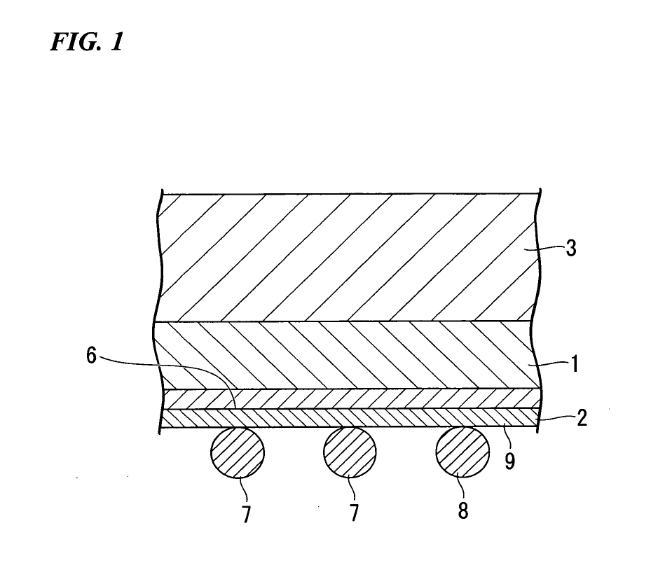

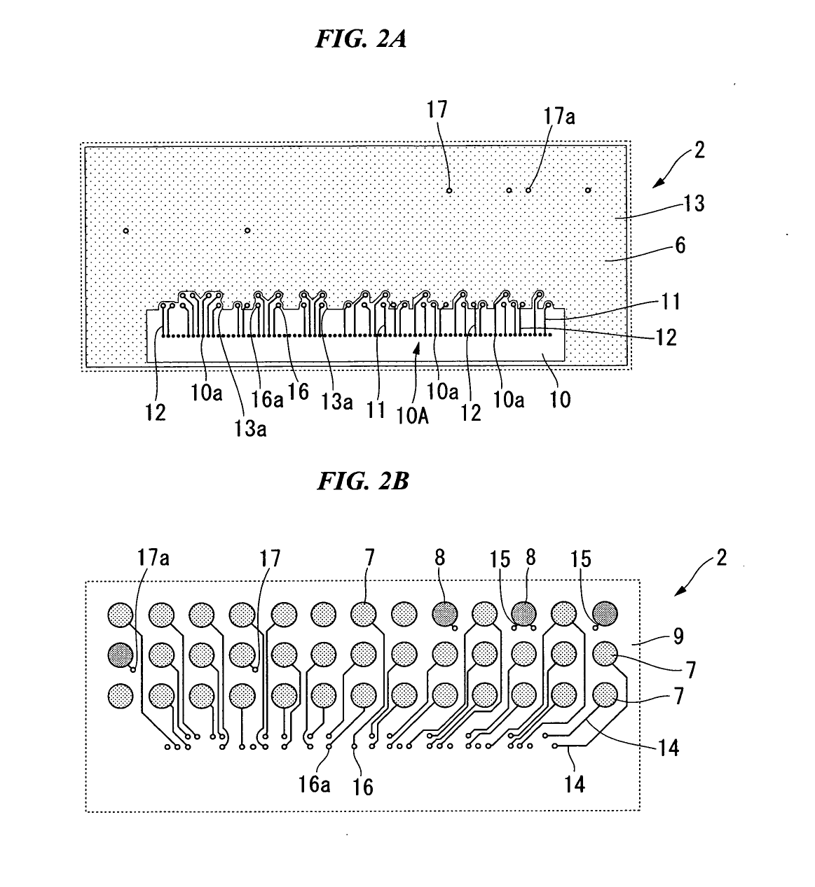

FIG. 1 is a longitudinal cross-sectional view of a semiconductor package according to a first embodiment of the present invention. FIG. 2A is a plan view, and FIG. 2B is a back view of a package substrate used in the semiconductor package according to the first embodiment.

As shown in FIG. 1, the semiconductor package according to the first embodiment includes a semiconductor chip 1, a package substrate 2 on which the semiconductor chip 1 is mounted, and a mold resin 3 which covers the semiconductor chip 1.

The semiconductor chip 1 includes assorted semiconductor circuits, a plurality of signal terminals for inputting and outputting electrical signals such as signals from the semiconductor circuits or power supply signals, a plurality of ground terminals, a plurality of signal bumps connected to the signal terminals, and a plurality of ground bumps connected to the ground terminals. In the figures, the terminals and the bumps are omitted.

The pluralities of signal bumps and the ground bumps are provided on a surface (i.e., the surface facing the package substrate) of the semiconductor chip 1. The signal bumps and the ground bumps are linearly arranged along the substantial longitudinal center of the surface, and are connected to later-described first signal wirings and ground wirings on the package substrate 2.

Although the materials and shapes of the signal bumps and the ground bumps are not particularly limited, the bumps may be made of gold or an alloy including gold, and may be formed in a cone-like shape such as a pyramid or conical.

The package substrate 2 includes a semiconductor chip mounting surface 6 and a terminal electrode forming surface 9 (i.e., a projection electrode forming surface). The semiconductor chip 1 is mounted on the semiconductor chip mounting surface 6. Pluralities of signal terminal electrodes (i.e., projection electrodes for signals) 7 as external input and output terminals and ground terminal electrodes (i.e., projection electrodes for grounding) 8 are arranged in an array pattern on the terminal electrode forming surface 9.

As shown in FIG. 2A, a longitudinal rectangular semiconductor chip mounting area 10, a plurality of first signal wirings 11, a plurality of ground wirings 12 and a ground conductive layer 13 are provided on the semiconductor chip mounting surface 6.

The first signal wirings 11, the ground wirings 12 and the ground conductive layer 13 may be made of a conductive material such as copper.

The plurality of the first signal wirings 11 are provided in linear patterns such that first ends thereof are arranged along a substantial longitudinal center of the semiconductor chip mounting area 10 to correspond to the signal bumps on the semiconductor chip 1, and second ends thereof are positioned in the vicinity of one outer edge of the semiconductor chip mounting area 10.

The plurality of the ground wirings 12 are provided in linear patterns such that first ends thereof are arranged alongside the first ends of the first signal wirings 11 and along the substantial longitudinal center of the semiconductor chip mounting area 10 to correspond to the ground bumps on the semiconductor chip 1, and second ends thereof are positioned in the vicinity of the one outer edge of the semiconductor chip mounting area 10.

The ground conductive layer 13 is provided in a predetermined area (i.e., a ground area) on the semiconductor chip mounting surface 6 in a solid (planar) pattern excluding the semiconductor chip mounting area 10 and the vicinity of the one outer edge of the semiconductor chip mounting area 10. The ground conductive layer 13 is not in contact with, and thus does not conduct with the first signal wirings 11 or with later-described conductors in signal through holes. The ground conductive layer 13 is in contact with, and thus conducts with the second ends of the ground wirings 12 and with later-described conductors in ground through holes.

FIG. 2A shows the ground area of the semiconductor chip mounting surface 6. Although not illustrated, the first signal wiring 11, the signal through holes and the like are similarly provided in areas other than the ground area of the semiconductor chip mounting surface 6.

In order to receive the semiconductor chip 1 thereon, the package substrate 2 is formed larger than the semiconductor chip 1. As shown in FIG. 2A, since the semiconductor chip mounting surface 6 is an elongated-shaped when seen in a plan view, the ground conductive layer 13 covers almost all the areas of the semiconductor chip mounting surface 6 excluding the semiconductor chip mounting area 10.

A conductor line 10A is formed along the longitudinal direction of the semiconductor chip mounting area 10 at the center of the elongated-shaped semiconductor chip mounting area 10. Each of conductors 10a constituting the conductor line 10A is connected with each of the first signal wirings 11 or the ground wirings 12. Accordingly, the first ends of the first signal wirings 11 and the ground wirings 12 are linearly arranged along substantially the center of the width of the semiconductor chip mounting area 10. The first signal wirings 11 extend from the conductors 10a toward the ground conductive layer 13, and are connected to later-described conductors 16 in the immediate vicinity of the ground conductive layer 13 without contacting the ground conductive layer 13. The conductors 16 are provided to penetrate the package substrate 2. The ground wirings 12 extend in parallel like the first signal wirings 11 on semiconductor chip mounting area 10, and are connected to an edge of the ground conductive layer 13 at the edge of the semiconductor chip mounting area 10. Where the plurality of the first signal wirings 11 are closely provided, a plurality of recesses 13a are provided at edges of the ground conductive layer 13 to provide clearance around the conductors 16, for the purpose of avoiding contact between the first signal wirings 11 and the ground conductive layer 13.

As shown in FIG. 2B, the signal terminal electrodes 7, the ground terminal electrodes 8, second signal wirings 14 and ground fine wirings 15 are provided on the terminal electrode forming surface 9.

The signal terminal electrodes 7 and the ground terminal electrodes 8 are spherically-shaped, and are made of a conductive material such as solder. The signal terminal electrodes 7 and the ground terminal electrodes 8 are arranged in an array pattern on the terminal electrode forming surface 9 excluding the area corresponding to the semiconductor chip mounting area 10 (i.e., the back surface of the semiconductor chip mounting area 10).

The second signal wirings 14 and the ground fine wirings 15 are made of a conductive material such as copper.

The second signal wirings 14 are provided in linear patterns with first ends connected to the signal terminal electrodes 7, and second ends connected to conductors 16a in signal through holes 16.

The ground fine wirings 15 are provided in short linear patterns with first ends connected to the ground terminal electrodes 8, and second ends connected to conductors 17a in ground through holes 17.

The signal through holes 16 are provided in the package substrate 2 at positions corresponding to the second ends of the first signal wirings 11 and the second signal wirings 14. The ground through holes 17 are provided in the package substrate 2 at positions corresponding to the second ends of the second ground wirings 15.

The first signal wirings 11 and the second signal wirings 14 are electrically connected via the conductors 16a provided in the through holes 16. Similarly, the ground conductive layer 13 and the ground fine wirings 15 are electrically connected via the conductors 17a provided in the through holes 17.

In the package substrate 2, the first signal wirings 11, the conductors 16a in the signal through holes 16, the second signal wirings 14 and the signal terminal electrodes 7 altogether constitute a signal circuit for transmitting electrical signals fed from the semiconductor chips 1. Similarly, the first ground wirings 12, the ground conductive layer 13, the conductors 17a in the ground through holes 17, ground fine wirings 15 and the ground terminal electrodes 8 altogether constitute a ground circuit.

The mold resin 3 is provided on the semiconductor chip mounting surface 10 of the package substrate 2 to cover the semiconductor chip 1. The mold resin 3 is made of, for example, epoxy resin. The mold resin 3 protects the semiconductor chip 1 and the wirings provided on the semiconductor chip mounting surface 10 from external influences (e.g., temperature, humidity and stress).

The semiconductor package is mounted on a printed circuit board with the terminal electrodes 7 and 8 deposited on the electrodes of the printed circuit board, and then subjected to reflowing.

In the semiconductor package mounted on the printed circuit board, electrical signals from the semiconductor chip 1 are output from the signal bumps, and then transmitted to the wirings of the printed circuit board via the signal circuits (i.e., the first signal wirings 11, the conductors 16a, the second signal wirings 14, and the signal terminal electrodes 7).

The current output from the ground bumps is grounded via the ground circuits (i.e., the first ground wirings 12, the ground conductive layer 13, the conductors 17a, the ground fine wirings 15 and the ground terminal electrodes 8).

In the semiconductor package, the ground conductive layer 13 is provided on the semiconductor chip mounting surface 6 at areas excluding the forming area of the first signal wirings 12, and the signal circuits excluding the first signal wirings 11 and the conductors 16a are provided on the terminal electrode forming surface 9. With this structure, a situation can be avoided in which the components of the signal circuits (i.e., the first signal wirings 11, the conductors 16a, the second signal wirings 14 and the signal terminal electrodes 7) and the ground conductive layer 13 approach closely. As a result, leakage of the signal current flowing through the signal circuits into the ground conductive layer 13 can be prevented. The characteristic impedance of the electrical signals output from the signal terminal electrodes 7 can be made substantially equal in the ground area and in the rest of the area. Thus, the signal quality can be kept high.

In the present embodiment, since the first signal wirings 12 are formed in a small area that includes the semiconductor chip mounting area 10 and the area near the one outer edge of the semiconductor chip mounting area 10, the ground conductive layer 13 can be made large. In this manner, the inductance of the ground circuit decreases and the generation of noise or a malfunction can be avoided.

The area of the second signal wirings 14 preferably accounts for not less than 70% of the total area of the first signal wirings 11 and the second signal wirings 14. In this manner, the forming area of the ground conductive layer 13 can be made sufficiently large and the inductance of the ground circuit can be sufficiently reduced.

Next, a second embodiment of the semiconductor package will be described.

The descriptions with regard to components similar to those of the first embodiment will be omitted.

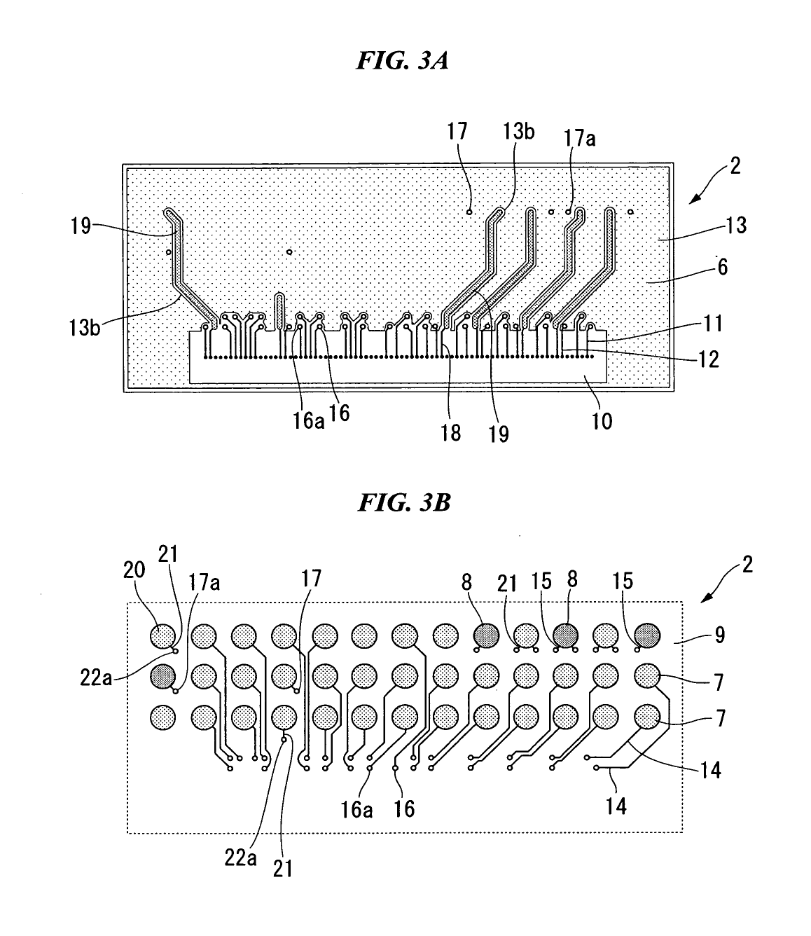

FIG. 3A is a plan view, and FIG. 3B is a back view of a package substrate used in a semiconductor package according to the second embodiment.

The semiconductor package of the second embodiment is the same as that of the first embodiment, except for the structure of signal circuits for transmitting electrical signals (i.e., power supply signal circuits) and patterns of a ground conductive layer.

As shown in FIG. 3A, in the semiconductor package according to the second embodiment, first power supply signal wirings 18 and second power supply signal wirings 19 are provided in a semiconductor chip mounting surface 6.

The first power supply signal wirings 18 are provided in linear patterns such that first ends thereof are arranged along a substantial longitudinal center of a semiconductor chip mounting area 10 alongside first ends of first signal wirings 11 to correspond to power supply signal bumps on the semiconductor chip 1, and second ends thereof are positioned in the vicinity of one outer edge of the semiconductor chip mounting area 10.

The second power supply signal wirings 19 are provided in linear patterns to enter the forming area of the ground conductive layer 13. First ends of the second power supply signal wirings 19 are connected to the first power supply signal wirings 18 and second ends of the second power supply signal wirings 19 are positioned in the vicinity of the areas corresponding to later-described power supply signal terminal electrodes (i.e., power supply signals projection electrodes) 20 (i.e., the back surface of the power supply signal terminal electrodes 20). Isolation areas 13b are provided on the ground conductive layer 13 in the vicinity of the second power supply signal wirings 19. The isolation areas 13b are formed in linear patterns so as to omit a part of the conductive layer and are wider than the second power supply signal wirings 19. The isolation areas 13b prevent the contact of the second power supply signal wirings 19 and the ground conductive layer 13. The second power supply signal wirings 19 are wider than the first power supply signal wirings 18.

The ground conductive layer 13 is provided at a predetermined area (i.e., a ground area) of the semiconductor chip mounting surface 6 in a solid (planar) pattern excluding the semiconductor chip mounting area 10, the area near the one outer edge of the semiconductor chip mounting area 10, the second power supply signal wirings 19 and the vicinity thereof. The ground conductive layer 13 is not in contact with, and thus does not conduct with the first signal wirings 11, conductors 16a in the signal through holes 16, the power supply signal wirings 18 and 19, and later-described conductors 22a in power supply signal through holes 22. The ground conductive layer 13 is in contact with, and thus conducts with the ground wirings 12 and with later-described conductors 17a in ground through holes 17. FIG. 3A shows a ground area of the semiconductor chip mounting surface 6. Although not illustrated, the first signal wirings 11, the first power supply signal wirings 18, the second power supply signal wirings 19, the signal through holes 16, the power supply signal through holes 22 and the like are similarly provided in the areas excluding the ground area of the semiconductor chip mounting surface 6.

As shown in FIG. 3B, a plurality of power supply signal terminal electrodes 20 and power supply signal fine wirings 21 are provided on a terminal electrode forming surface 9.

The plurality of the power supply signal terminal electrodes 20 are arranged in an array pattern alongside the signal terminal electrodes 7 that output electrical signals fed from the semiconductor chip 1 and the ground terminal electrodes 8.

The power supply signal fine wirings 21 are provided in short linear patterns with first ends connected to the power supply signal terminal electrodes, and second ends connected to conductors 22a in the power supply through holes 22.

The power supply signal through holes 22 are provided in the package substrate 2 at positions corresponding to the second ends of the second power supply signal wirings 19 and the power supply signal fine wirings 21. The second power supply signal wirings 19 and the power supply signal fine wirings 21 are electrically connected via the conductors 22a provided in the power supply signal through holes 22.

In the package substrate 2, the first power supply signal wirings 18, the second power supply signal wirings 19, the conductors 22a in the power supply signal through holes 22, the power supply fine wirings 21 and power supply signal terminal electrodes 20 altogether constitute a power supply circuit for transmitting power supply signals.

In the second embodiment, the same advantageous effects as those of the first embodiment can be obtained.

In the second embodiment, part of the power supply circuits (i.e., the second power supply signal wirings 19) is provided on the semiconductor chip mounting surface 6. In this manner, the wiring density of the terminal electrode forming surface 9 decreases, and in the process of forming the wirings on the terminal electrode forming surface 9, the conductor patterning used as the wirings can be readily formed.

Since the second power supply signal wirings 19 are wider than the first power supply signal wirings 18, the inductance in the power supply circuits can be advantageously reduced.

Although the wide second power supply signal wirings 19 are provided to enter the forming area of the ground conductive layer 13 in the second embodiment, the area of the ground conductive layer 13 can be sufficiently large even if the forming area of the ground conductive layer 13 is reduced by the area of the second power supply signal wirings 19. This is because, as described in the first embodiment, on the semiconductor chip mounting surface 6, the forming area of the ground conductive layer can be made larger than the terminal electrode forming surface 9. Accordingly, the inductance in the ground circuits can be reduced while the inductance in the power supply circuits can also be reduced.

Next, a third embodiment of the semiconductor package will be described.

The descriptions with regard to the components similar to those of the first embodiment will be omitted.

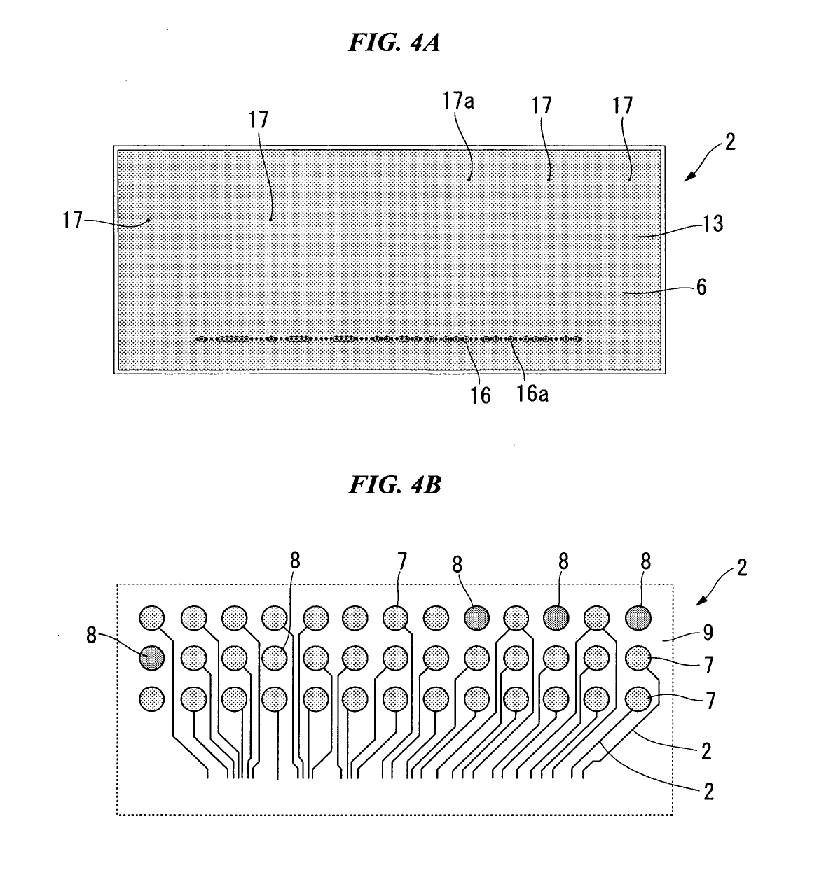

FIG. 4A is a plan view, and FIG. 4B is a back view of a package substrate used in a semiconductor package according to the third embodiment.

The semiconductor package of the third embodiment is the same as that of the first embodiment, except for the structures of signal circuits and ground circuits, and patterns of a ground conductive layer.

As shown in FIG. 4, in the semiconductor package of the third embodiment, a package substrate 2 includes a semiconductor chip mounting surface 6 and a terminal electrode forming surface 9. A semiconductor chip 1 is mounted on the semiconductor chip mounting surface 6. A plurality of signal terminal electrodes 7 and ground terminal electrodes 8 as external input and output terminals are arranged in an array pattern on the terminal electrode forming surface 9.

As shown in FIG. 4A, a ground conductive layer 13 is provided at a predetermined area (i.e., ground area) of the semiconductor chip mounting surface 6 in a solid (planar) pattern excluding later-described signal through holes 16 and the vicinity thereof.

As shown in FIG. 4B, pluralities of signal terminal electrodes 7, ground terminal electrodes 8, and signal wirings 23 are provided on the terminal electrode forming surface 9.

The structures of the signal terminal electrodes 7 and the ground terminal electrodes 8 are the same as those of the first embodiment.

The signal wirings 23 are provided in linear patterns with first ends connected to the signal terminal electrodes 7, and second ends connected to conductors 16a in the signal through holes 16.

The plurality of the signal through holes 16 are provided on the package substrate 2 along a substantial longitudinal center of the semiconductor chip mounting area 10 to correspond to signal bumps of the semiconductor chip 1. A plurality of ground through holes 17 are provided on the package substrate 2 to correspond to the ground terminal electrodes 8. The conductors 16a and 17a are filled in the through holes 16 and 17, respectively. The signal bumps of the semiconductor chip 1 are directly connected to the conductors 16a in the signal through holes 16, and are electrically connected to the signal wirings 23 via the conductors 16a. The ground bumps of the semiconductor chip 1 are connected to the ground conductive layer 13 and are electrically connected to the ground terminal electrodes 8 via the ground conductive layer 13 and the conductors 17a in the through holes 17.

In the package substrate 2, since the through holes 16 and 17 are filled with the conductors 16a and 17a, signal bumps can be directly connected to the through holes 16, and the ground terminal electrodes 8 can be directly provided on the through holes 17.

In the package substrate 2, the conductors 16a in the signal through holes 16, the signal wirings 23, and the signal terminal electrodes 7 altogether constitute a signal circuit for transmitting signals fed from the semiconductor chips and power supply signals. Similarly, the ground conductive layer 13, the conductors 17a in the ground through holes 17, and the ground terminal electrodes 8 altogether constitute a ground circuit.

In the semiconductor package according to the third embodiment, the ground conductive layer 13 is provided on the semiconductor chip mounting surface 6, and the signal circuits excluding the conductors 16a in the signal through holes 16 are provided on the terminal electrode forming surface. With this structure, a situation can be avoided in which the components of the signal circuits (i.e., the conductors 16a, the signal wirings 23 and the signal terminal electrodes 7) and the ground conductive layer 13 approach closely. As a result, leakage of the signal current flowing through the signal circuits into the ground conductive layer 13 can be prevented. The characteristic impedance of the electrical signals output from the signal terminal electrodes 7 can be made substantially equal in the ground area and in the rest of the area. Thus, the signal quality can be kept high.

Further, the ground conductive layer 13 can be formed in a large area since it can be provided on substantially the entire area of the semiconductor chip mounting surface 6 excluding the signal through holes 16 and the vicinity thereof. As a result, the inductance in the ground circuits decreases, thereby preventing the generation of noise or a malfunction.

The structures of the components of the semiconductor package have been shown for illustrative purposes only, and may be suitably modified without departing the scope of the present invention.

For example, the connection between the terminals of the semiconductor chip and the wirings of the package substrate may be established by wirings, instead of bumps.

Although only one package substrate is used in the semiconductor package according to the present embodiment, monolayer or laminated multilayer package substrates may also be used.

A practical example of the present invention may include dynamic random access memory (DRAM) mounted on a dual inline memory module (DIMM).

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor package comprising:
a semiconductor chip which includes a signal terminal for inputting and outputting electrical signals and a ground terminal; and
a package substrate which includes a semiconductor chip mounting surface on which the semiconductor chip is mounted, and a terminal electrode forming surface on which a signal terminal electrode electrically connected to the signal terminal and a ground terminal electrode electrically connected to the ground terminal are arranged in an array pattern,
wherein:
on the semiconductor chip mounting surface, there is provided a first signal wiring connected to the signal terminal, a ground wiring connected to the ground terminal, and a ground conductive layer connected to the ground wiring and is provided in a planar pattern in an area excluding the forming area of the first signal wiring;
on the terminal electrode forming surface, there is provided a second signal wiring connected to the signal terminal electrode, and a ground fine wiring connected to the ground terminal electrode; and
the first signal wiring and the second signal wiring are connected via a conductor filled in a signal through hole penetrating the package substrate, and the ground conductive layer and the ground fine wiring are connected via a conductor filled in a ground through hole penetrating the package substrate.

2. A semiconductor package according to claim 1, wherein the first signal wiring and the ground wiring are formed in the semiconductor chip mounting area and in the vicinity of an outer edge of the semiconductor chip mounting area.

3. A semiconductor package according to claim 1, wherein the area of the second signal wiring accounts for not less than 70% of the total area of the first signal wiring and the second signal wiring.

4. A semiconductor package according to claim 1, wherein:
a first power supply signal wiring connected to a power supply signal terminal of the semiconductor chip and a second power supply signal wiring connected to the first power supply signal wiring are provided on the semiconductor chip mounting surface;
a power supply signal terminal electrode and a power supply signal fine wiring connected to the power supply signal terminal electrode are provided on the terminal electrode forming surface; and
the second power supply signal wiring and the power supply signal fine wiring are connected via a conductor filled in a power supply signal through hole penetrating the package substrate.

5. A semiconductor package according to claim 4, wherein the second power supply signal wiring is provided to enter the forming area of the ground conductive layer.

6. A semiconductor package according to claim 4, wherein the second power supply signal wiring is wider than the first power supply signal wiring.

7. A semiconductor package comprising:
a semiconductor chip which includes a signal terminal for inputting and outputting electrical signals and a ground terminal; and
a package substrate which includes a semiconductor chip mounting surface on which the semiconductor chip is mounted, and a terminal electrode forming surface on which a signal terminal electrode electrically connected to the signal terminal and a ground terminal electrode electrically connected to the ground terminal are arranged in an array pattern,
wherein:
a ground conductive layer connected to the ground terminal electrode and formed in a planar pattern is provided on the semiconductor chip mounting surface;
a signal wiring connected to the signal terminal electrode is provided on the terminal electrode forming surface; and
the signal terminal electrode and the signal wiring of the semiconductor chip are connected via a conductor filled in a signal through hole penetrating the package substrate, and the ground conductive layer and the ground terminal electrode are connected via a conductor filled in a ground through hole penetrating the package substrate.

8. A semiconductor package according to claim 1, wherein the signal terminal and the ground terminal of the semiconductor chip are bumps.

9. A semiconductor package according to claim 7, wherein the signal terminal and the ground terminal of the semiconductor chip are bumps.
